(19) United States
(12) Patent Application Publication
(10) Pub. No.: US 2011/0019370 A1
(43) Pub. Date: Jan. 27, 2011

(54) FLEXIBLE CIRCUIT MODULE

(75) Inventor: Wei-hu Koh, Irvine, CA (US)

Correspondence Address: BAKER & MCKENZIE LLP;PATENT DEPARTMENT, 2001 ROSS AVENUE, SUITE 2300, DALLAS, TX, 75201, US

(73) Assignee: GAINTEAM HOLDINGS LIMITED, Tsing Yi (HK)

(21) Appl. No.: 12/510,157

(22) Filed: Jul. 27, 2009

(51) Int. Cl. H05K 1/18; H05K 3/30

(52) U.S. Cl. 361/749; 29/832

(57) ABSTRACT

This disclosure pertains to a flexible circuit module and related methods of manufacturing and applications for such a flexible circuit module. In one exemplary embodiment, the flexible circuit module comprises a flexible substrate, at least one flexible chip element, and a flexible top layer disposed over the flexible substrate and the flexible chip element. According to an aspect, a flexible circuit module is used in flexible electronic devices. According to another aspect, a flexible circuit module is attached to the inner surface of an electronic device and connected to the device main board. According to another aspect, a flexible circuit module is used in the place of a current PCB in a PCBA. According to another aspect, a flexible circuit module is rolled up and used inside an electronic device. According to another aspect, a flexible circuit module is molded.

### TECHNICAL FIELD

This disclosure relates generally to circuits and chip elements, and more specifically, to flexible circuits and flexible chip elements.

### BACKGROUND

Conventional printed wiring board assemblies are assembled on rigid, laminated, glass-epoxy printed circuit boards (PCBs) using surface mount technology processes. Nonvolatile NAND flash chip packages, for example, are assembled on a rigid PCB board to form a PCB Assembly (PCBA) that is then used as the core for making flash memory cards, USB thumb drives, and memory storage modules. An internal memory module, be it a dynamic random access memory (DRAM) based dual inline memory module (DIMM) or a NAND based solid-state drive module, is typically connected to the mainboard of a device by means of a socket. Addition of such rigid memory modules to a mainboard requires more space for the mainboard, adds more vertical height and thickness to the board assembly, adds more weight to the mainboard assembly, and adds complexity to electronic device design.

### BRIEF SUMMARY

This disclosure pertains to a flexible circuit module and related methods of manufacturing and applications for such a flexible circuit module.

In an aspect a flexible circuit module is provided, which in an exemplary embodiment comprises a flexible substrate and at least one flexible chip disposed on the flexible substrate. A flexible top layer is laminated to the top surface of the flexible substrate, wherein the at least one flexible chip is disposed in between the flexible substrate and the flexible top layer.

In another aspect, a method for manufacturing a flexible circuit module is provided. In one embodiment, such a method may comprise providing a flexible substrate. The method may further include disposing at least one flexible chip on a top surface of the flexible substrate and bonding a flexible top layer to the top surface of the flexible substrate, wherein the at least one flexible chip is disposed in between the flexible substrate and the flexible top layer.

In another aspect, an electronic device is provided, which in an exemplary embodiment comprises an outer casing and a flexible circuit module. The flexible circuit module comprises a flexible substrate and at least one flexible chip disposed on the flexible substrate. A flexible top layer is laminated to the top surface of the flexible substrate, wherein the at least one flexible chip is disposed in between the flexible substrate and the flexible top layer. The flexible circuit module is disposed on an inner layer of the outer casing of the memory device.

### BRIEF DESCRIPTION OF THE DRAWINGS

FIG. 1 illustrates a conventional module with a rigid board;

FIG. 2 illustrates a flexible circuit arrangement, in accordance with the present disclosure;

FIG. 3 illustrates a close up view of a flexible circuit arrangement, in accordance with the present disclosure;

FIGS. 4A-4C illustrate various arrangements of a flexible circuit, in accordance with the present disclosure;

FIG. 5 illustrates a rolled up flexible circuit, in accordance with the present disclosure;

FIG. 6 illustrates a cross sectional view of a flexible circuit arrangement, in accordance with the present disclosure; and

FIG. 7 is a schematic diagram illustrating an embodiment of the manufacturing processes used to manufacture a flexible circuit, in accordance with the present disclosure.

### DETAILED DESCRIPTION

In view of the above-described disadvantages of rigid PCBA, there is a need for a lightweight, thin, flexible circuit module adaptable to accommodate a variety of current and future electronic device designs without adding the height or thickness of the device main board. It would be desirable for a thin, lightweight, and flexible circuit module to fit inside of flexible or curved electronic devices. A flexible circuit may also be used to replace current PCBAs in memory cards to add more capacity and reduce weight. Providing a flexible circuit for use in devices with uneven support surfaces is also desirable.

FIG. 1 is a drawing illustrating a conventional rigid circuit board assembly 100. Chip elements 110 are surface mount devices (SMDS) and are assembled on a rigid printed circuit board (PCB) 120. Chip elements 110 have short pins or leads 130 which are soldered to solder pads on board 120. The gold finger contact pads 140 disposed along one edge of the board 120 provide electrical connections when the board 120 is inserted into a connecting socket in a motherboard (not shown).

Unfortunately, such rigid circuits and circuit elements add complexity and cost to the manufacturing, installation, and design processes for electronic devices. Moreover, incorporating such rigid components into devices that are designed to conform to various external geometries is difficult. Many futuristic devices, including telecommunications devices, may employ conforming, flexible features that can be attached closely and tightly to a human body, such as biosensors with curved body designs to. For example, a watch-like GPS (global positioning system) or a mobile phone could employ conforming, flexible features and designs to better fit a human wrist. Other examples include organic Light Emitting Diode (OLED) displays, flexible keypads, and flexible touch pads. In addition, electronic devices are becoming smaller and reducing the volume and size of circuit components is often a design goal. Rigid circuit boards are a design constraint on reducing the size of electronic devices. Further, current and future devices may include uneven support surfaces for circuit components and rigid, planar circuit boards are unsuitable for such applications.

To overcome problems associated with conventional techniques, a flexible circuit module constructed according to the principles disclosed herein provides for the use of a flexible substrate, flexible chip elements, and a flexible protective layer. Such a flexible circuit module may be used in any application where having a flexible circuit is advantageous including, but not limited to, providing a circuit assembly for a flexible electronic device, attaching to the inside of a rigid electronic device's case, being molded into a variety of shapes for a variety of circuit applications including memory modules and cards, being rolled or configured into a variety of shapes to facilitate the design of electronic devices, being used in electronic devices with uneven support surfaces.

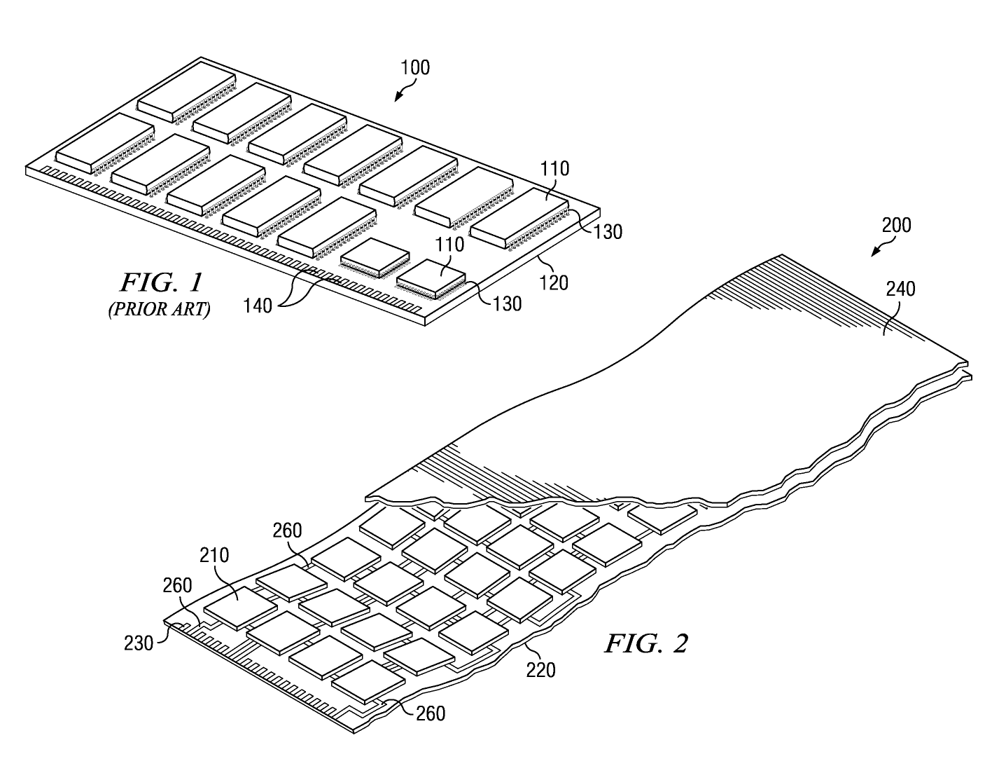

FIG. 2 illustrates an embodiment of a flexible circuit module 200 in accordance with the present disclosure. At least one flexible chip element 210 is disposed on at least one surface of the flexible substrate 220. In some embodiments, a plurality of flexible chip elements 210 are disposed on the flexible substrate 220. The substrate layer 220 contains appropriate metal traces and exposed interconnection pads to connect to the chip elements 210 and embedded passive elements on the surface (not shown). The metal traces 260 can be copper or thin film gold. When copper traces and contact pads are used, organic solder preserve (OSP) may be used to protect the copper from oxidation. A flexible top layer 240 is laminated to the flexible substrate 220, sandwiching the flexible chip elements 210 between the flexible top layer 240 and the flexible substrate 220. Both the flexible substrate 220 and flexible top layer 240 are made of one or more flexible materials to impart flexibility to the flexible module 200. Such flexibility allows the flexible circuit module 200 to easily fit inside curved spaces, small electronic devices, electronic devices with space constraints, clothing, or any other space where it would be advantageous to have a thin, flexible circuit.

The flexible substrate 220 may be made of any suitable flexible material known in the art, such as polyimide or liquid crystal polymer. The flexible top layer 240 may also be made of thin polymer films such as polyimide, liquid crystal polymer, or any other flexible material known in the art. In an embodiment, the flexible top layer 240 is made of a thin sheet of transparent polymer film. In another embodiment, the flexible top layer 240 is opaque. In some embodiments, the flexible substrate 220 and top layer 240 may be made of the same flexible material, but in some other embodiments, they may be made of different materials. In some particular embodiments, to improve the flexibility of the flexible circuit module 200, the thickness of the flexible substrate 220 and the thickness of the flexible top layer 240 are both less than 15 μm.

The flexible top layer 240 can be laminated to the flexible substrate 220 by mechanical or chemical means. In some embodiments, the flexible top layer 240 is laminated to the flexible substrate 220 using adhesive lamination, solvent welding, vacuum forming, pressing, or any other appropriate lamination method without causing damage to the flexible chip elements 210. The lamination of the flexible top layer 240 to the flexible substrate 220 allows the flexible chip elements 210 to be sealed from the environment. The flexible top layer 240 is also operable to provide mechanical protection for the flexible chip elements and any other circuit elements and may act as an electrical insulator. In an exemplary embodiment, the flexible top layer 240 and the flexible substrate 220 cooperate to provide a hermetic seal for the flexible chip elements 210. While the top layer 240 is mainly for mechanical protection, electrostatic discharge (ESD) provisions may be incorporated on the surface of the layer 240 for ESD protection. The top layer can further be used for providing or applying a thin layer or coating of tacky or pressure-sensitive adhesive. Thus, when the flex memory is used as an inner lining of an enclosure, such as the plastic or metal casing of a notebook computer or a mobile phone, the adhesive on the top layer is used to glue or attach the flex memory module to form an inner lining.

In addition to the flexible substrate 220 and the flexible top layer 240, the flexible chip elements 210 can also be designed to have substantial flexibility and thereby impart additional flexibility to the flexible memory module 200. In some embodiments, the thickness of the flexible chip elements 210 is less than 25pm to impart flexibility to the flexible chip element 210. For example, a bare die silicon chip with a thickness of 20 μm is obtained by dicing a thinned silicon wafer having the same thickness. Wafer thinning is accomplished by a first mechanical polishing followed by appropriate chemical mechanical polishing (CMP) processes to reach the desired thickness.

In an exemplary embodiment, the flexible chip elements 210 are embedded in the flexible substrate 220. In another embodiment, the flexible chip elements 210 are not embedded, but are electrically connected to the flexible substrate 220 circuit traces via any method known in the field including, but not limited to flip chip bonding.

In an embodiment, the flexible chip elements 210 are silicon NAND flash memory chips. In another embodiment, the flexible circuit module 200 comprises at least one passive chip element (e.g., capacitors, inductors, and/or resistors, not shown). In another embodiment the flexible circuit module 200 comprises a memory controller (e.g., a controller die, not shown). In another embodiment, the flexible circuit module 200 comprises a surface mount component.

It is to be appreciated by one of ordinary skill in art that the flexible circuit module 200 can be modified to include additional components to accommodate design needs. For example, the flexible circuit module 200 may include a passive element, memory controller, and/or surface mount components, and the passive elements may also be flexible. The controller die can be thinned to 25 μm and connected to the flexible substrate 220, e.g. by flip chip bonding. In some embodiments, the flexible circuit module 200 has additional components and the passive elements are not flexible, but are substantially small and narrow (e.g., 0201 or 01005 sized discrete components), such that the flexible circuit module 200, as a whole, is still flexible and bendable. Using 0201 or 01005 sized components can be embedded inside a flexible circuit without substantially affecting the overall flexibility. In another embodiment, the flexible circuit module 200 has additional components, and rigid components (e.g., a resonator crystal or controller package) are not placed on the flexible circuit module 200. In this embodiment, the flexible circuit module 200 contains the flexible chip elements and some small passive elements (flexible or not flexible). The larger and the rigid components are included on another bridge board, or optionally directly on a motherboard and are connected to the flexible circuit module.

In an exemplary embodiment, the flexible circuit module 200 comprises connecting pads 230 which allow for connection to a main board. Connecting pads 230 may comprise any type of suitable electrical connecting pad structure including, but not limited to, gold fingers, metal traces, or socket connectors. In an embodiment, the connecting pads 230 and circuit metal traces 260 leading to and connecting with the pads 230 are pre-fabricated on the substrate layer 220, such as a copper/polymide substrate.

In an embodiment, the flexible chip elements 210 are connected to the flexible substrate 220 by an interconnection between the flexible chip elements 210 flip chip bumps and the flexible substrate 220 connecting pads. In an embodiment, the substrate 220 comprises a two metal layer circuit with bonding pads and metal traces that may be connected by means of a conductive via (not shown) within the substrate.

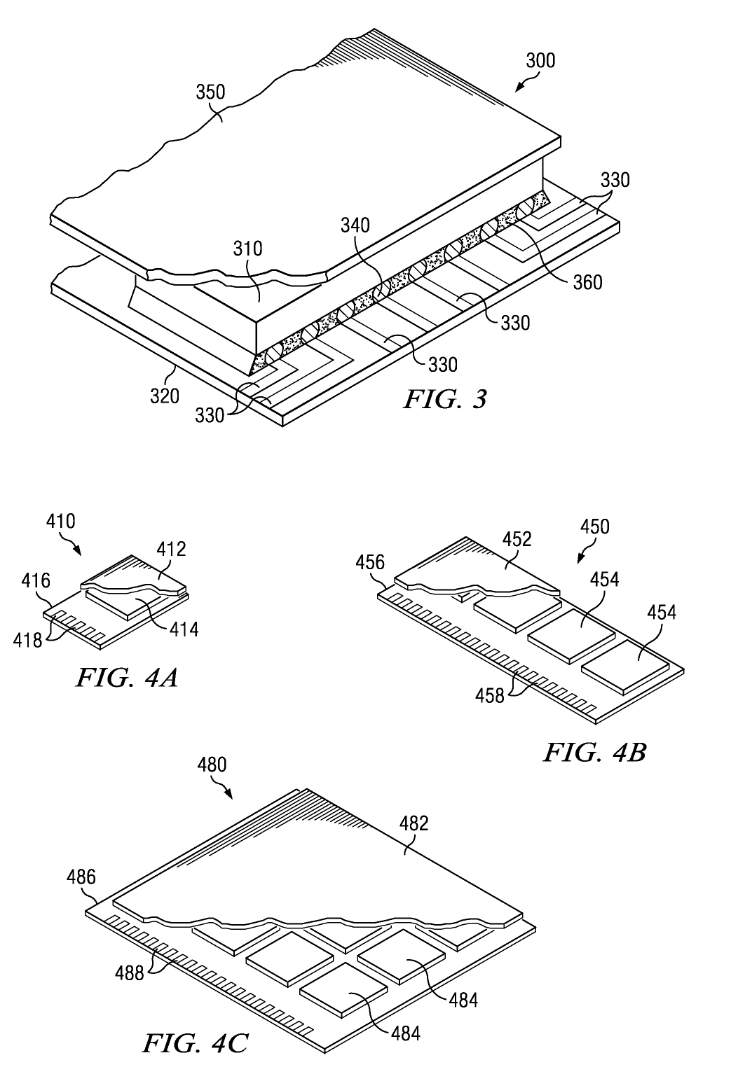

FIG. 3 is a focused view of the module 200. In an embodiment, the interconnection between the flexible chip elements 310 and the flexible substrate 320 connecting pads 330 is made by using micro bumps 340 of electrically conducting materials. In an embodiment, a compliant underfill encapsulant 360 is applied between the flexible chip elements 310 and the substrate 320. In another embodiment, the flexible chip elements 310 are connected to the flexible substrate 320 via a conventional wire bond. Interconnection the flexible chip elements 310 and the flexible substrate 320 may also be achieved by gold to gold bumping, using thermal compression bonding equipment. The flexible chip elements 310 can also be gang bonded to the flexible substrate 320, and all of the bumps on a flexible chip element 310 are bonded to the flexible substrate 320 substantially simultaneously. One way to achieve this is by using a flip chip bonding press with an elevated temperature. The flexible chip elements 310 are screen printed with conductive adhesive and then flip chip bonded to the flexible substrate 320.

In an embodiment, the process of connecting the flexible chip elements 310 to the flexible substrate 320 can be achieved via reel-to-reel processes. The entire flexible circuit module assembly process can be achieved using reel-to-reel technology with appropriate equipment allowing for fast throughput and lower production cost. In another embodiment, only part of the flexible circuit module assembly process is achieved using reel-to-reel technology. After the flexible chip elements 310 are bonded on the flexible reeled substrate, the process of bonding a flexible top layer 350 over the flexible chip elements 310 and flexible substrate 320 may also be achieved via reel-to reel processes. Compared to the assembly process for a rigid board panel, an embodiment wherein assembling the flexible circuit module is achieved using a reel-to-reel process may save substantial time and costs. The reel-to-reel process is discussed below in relation to FIG. 7.

In an embodiment, after a flexible circuit module is made, individually designed strips, arrays, or single elements may be punched out or cut from the completed strips or panels of flexible circuit module. The design of the flexible circuit module panel includes individual sets of goldfinger connector pads for each strip, array, or single element. FIGS. 4A-4C are drawings illustrating various cut or punched out embodiments for a flexible circuit module 410, 450, 480. In an embodiment, a module 410 comprises a single chip element 414 on a flexible substrate 416 with a flexible top layer 412, and appropriate connecting pads 418. In another embodiment, a long strip module 450 comprises flexible chip elements 454 positioned on a flexible substrate 456 with a flexible top layer 452, and appropriate connecting pads 458. In another embodiment, a sheet module 480 comprises an array of flexible chip elements 484 positioned on a flexible substrate 486 with a flexible top layer 485, and appropriate connecting pads 488. In an embodiment, the singular, strip, or array flexible circuit modules 400, 450, 480 connect to a bridge board with a controller unit via the connecting pads. At one end, the flexible circuit modules, 400, 450, 480 has a terminal (e.g. gold plated pads, as shown). Solder can be applied to connect the pads to the bridge board. In another embodiment, wire is used. In an exemplary embodiment, an external connector, e.g., a unshaped clamp, is used to connect the modules 400, 450, 480 to a main board.

In an embodiment, the flexible circuit elements 484 comprise NAND flash memory and a sheet or array arrangement comprises a 4×4 array (or 16 flexible memory chips). By way of example only, if one flexible memory chip has 8 GB of memory, then the sheet or array would have 128 GB of memory.

In an embodiment, a flexible circuit module strip or array is rolled up to form a circular roll or an ellipsoid shaped coil to achieve high memory capacity. The connecting gold finger pads are located on one end. An external case, including, but not limited to, a flash memory drive, a USB thumb drive, or an SSD drive, encloses the roll, providing a high capacity storage device—e.g., 512 GB (gigabytes). In another embodiment, a flexible circuit module element, strip, or array is stacked with other flexible circuit module elements, strips, or arrays, and enclosed in an external case.

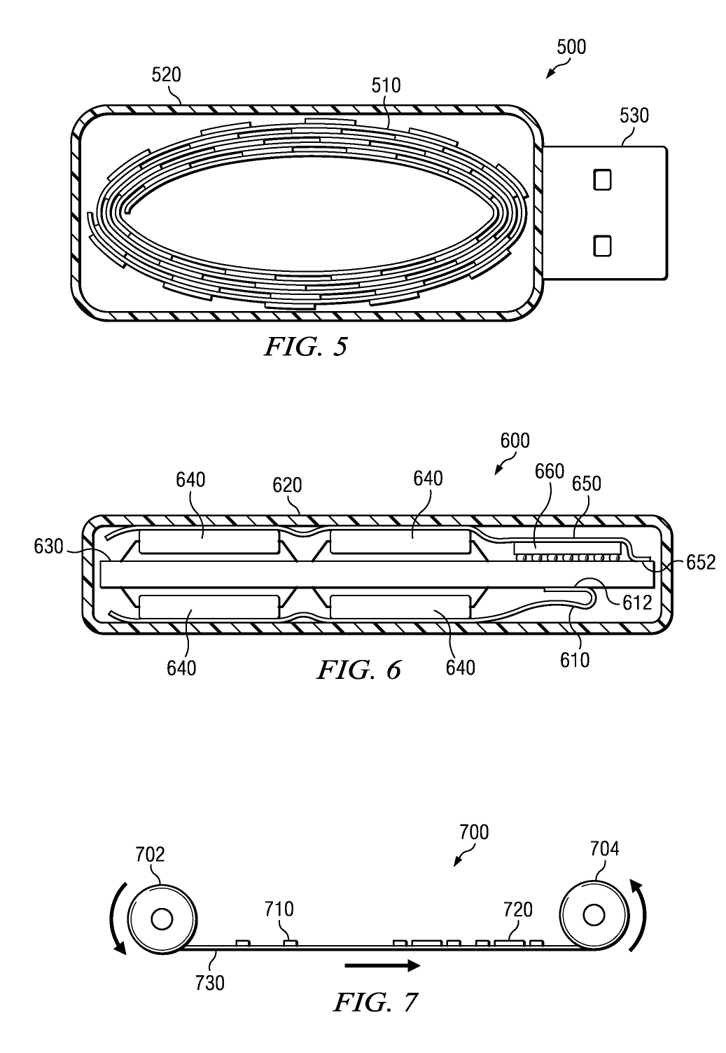

FIG. 5 is a drawing illustrating an embodiment of a flexible circuit module 510 rolled up to form a circular roll or an ellipsoid shaped coil inside of USB drive 500. The USB drive 500 comprises a casing 520 and a connector 530.

In an embodiment, an element, strip or array of flexible circuit module is molded using appropriate microelectronic grade molding compounds to form various types of memory cards including, but not limited to, micro SD cards, mini-SD cards, and SD cards. A mold can be made for individual elements of flexible circuit module and may form one card. Alternatively, a large block map mold can be used on a strip or array of flexible circuit module and multiple cards are cut or punched out from the map mold. In another embodiment, multiple elements are molded to form a single card. And in yet another embodiment, the flexible circuit module elements, strips or arrays are stacked prior to the encasing or molding process to substantially increase the memory capacity of each card.

In another embodiment, an element, strip or array of flexible circuit module is molded to form credit-card sized memory cards for use in various form factors and devices, including, but not limited to, a PCI express card, an external USB drive, or a solid-state flash drive. A mold can be made of an individual element of flexible circuit module and may form one card. Alternatively, a large block map mold can be used on a strip or array of flexible circuit module and multiple cards are cut or punched out from the map mold. In another embodiment, multiple elements are molded to form a single card. And in yet another embodiment, the flexible circuit module elements, strips or arrays are stacked prior to the encasing or molding process to substantially increase the memory capacity of each card.

In an embodiment, an epoxy-based molding compound is used to mold the flexible circuit, resulting in a substantially rigid card. If a flexible card is desired, a flex thermoplastic material is used to encase the flexible circuit during the molding process. The resulting cards can be several millimeters thick and may still remain flexible and bendable.

In an embodiment, a flexible circuit module is connected to the main board of an electronic device, such as a smartphone, a netbook, or a mini-notebook computer. The flexible circuit can be connected to such a main board via a micro socket at one edge or corner of the board. In an embodiment, the full body of the flexible circuit module is placed over a fully populated main board with components with uneven heights. This configuration saves the size of the main board and simplifies its circuit board design because the flexible storage memory can be plugged in to provide expanded memory capacity. In another embodiment, the main board contains flash storage memory and the flexible circuit module provides additional, expandable memory.

In an embodiment, a flexible circuit module is mounted as the interior lining on the inside of a device casing, including, but not limited to, the casing for a smart phone, a netbook computer, a pico-projector, or a wristwatch. In an embodiment, the flexible circuit module is adhered or glued to the inside of the device casing. The flexible circuit module can be connected to a main board PCBA assembly inside the case using a flexible connector. In an embodiment, the flexible circuit module is pre-lined inside of the device. This configuration may simplify the PCBA main board design and size, reduce device size and weight, and enable the device to contain a high capacity internal memory. Because of the flexible nature of the flexible circuit module, the module can be attached to and may fit a variety of surfaces including curved surfaces and square surfaces, with the flexible circuit module fitting snugly against the surface to save space.

In an embodiment, a flexible circuit module is attached to the inside of a housing so as not to displace existing internal structures and space reserved for a PCBA. The flexible circuit module can be incorporated into most existing devices with substantially no change to the design or dimensions of the internal PCBA or the dimensions, size, or weight of the device. For example, a flexible circuit module can be attached to the inside of a casing for a pico projector to substantially increase its internal memory and storage capacity without substantially affecting its weight or size. A flexible circuit module can also be wrapped like a spiral tube or cylinder inside a round casing to form a memory stick card.

FIG. 6 is a drawing illustrating the side view of an electronic device 600, including, but not limited to, a pico projector or a smart phone. Inside the casing 620 is a regular PCBA main board with components 640 including a ball grid array (BGA) 660 assembled on a rigid PCB 630. A flexible circuit module 610 lines the inside lower portion of the casing 620 and connects to the main board 630 at the contact area 612. Another flexible circuit module 650 lines the upper inner portion of the casing 620 and connects to the main board 630 at the contact area 652. In an embodiment, the connection between the flexible circuit modules 610, 650 and the main board is achieved via a flexible connector.

FIG. 7 illustrates an embodiment of a reel-to-reel manufacturing process 700 used to manufacture a flexible circuit. A supply reel or feed reel 702 contains a spool of flexible substrate 730. The flexible substrate 730 is then fed through mechanical guides (not shown) and undergoes various processes including SMD passive components 710 and/or IC chip components 720 being coupled to the flexible substrate 730. Finally, the flexible substrate 730 is attached to a second, initially empty, takeup reel 704 which re-spools the substrate 730 with the chip components attached. The interconnection between the flexible chip elements, the flexible substrate, and the flexible top layer can all be achieved via reel-to-reel processes including, but not limited to the various interconnection methods discussed in relation to FIG. 3.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A flexible circuit module, the module comprising:
a flexible substrate;
at least one flexible chip disposed on a top surface of the flexible substrate; and
a flexible top layer laminated to the top surface of the flexible substrate, wherein the at least one flexible chip is disposed in between the flexible substrate and the flexible top layer; and
wherein the flexible top layer forms a conformal layer on the entire top surface of the flexible substrate.

2. The module of claim 1, wherein the flexible top layer is chemically bonded to the top surface of the flexible substrate.

3. The module of claim 1, wherein the at least one flexible chip is partially embedded in the flexible substrate.

4. The module of claim 1, wherein the at least one flexible chip comprises a memory chip.

5. The module of claim 1, further comprising at least one passive chip.

6. The module of claim 1, further comprising at least one memory controller.

7. The module of claim 1, further comprising at least one surface mount component.

8. The module of claim 1, wherein the flexible substrate comprises at least one connecting pad.

9. The module of claim 1, wherein the flexible top layer is transparent.

10. The module of claim 1, wherein the flexible top layer is made of a polymer material.

11. The module of claim 1, wherein the flexible top layer cooperates with the flexible substrate to provide a hermetic seal for the at least one flexible chip.

12. The module of claim 1, wherein the at least one flexible chip has a thickness that is less than 25 micrometers thick.

13. The module of claim 1, wherein at least one input/output interface of the at least one flexible chip is connected to at least one connecting pad of the flexible substrate.

14. (canceled)

15. (canceled)

16. (canceled)

17. (canceled)

18. (Canceled)

19. (canceled)

20. (canceled)

21. (canceled)

22. (canceled)

23. (canceled)

24. (canceled)

25. A flexible circuit module, the module comprising:
a flexible substrate;
at least one flexible chip disposed on a top surface of the flexible substrate; and
a flexible top layer laminated to a portion of the top surface of the flexible substrate, wherein the at least one flexible chip is disposed in between the flexible substrate and the flexible top layer; and
wherein the flexible top layer forms a conformal layer on the at least one flexible chip, and wherein the flexible top layer cooperates with the flexible substrate to provide a hermetic seal for the at least one flexible chip, thereby sealing the at least one flexible chip from the environment.

26. The module of claim 25, wherein the flexible top layer is chemically bonded to the top surface of the flexible substrate.

27. The module of claim 25, wherein the at least one flexible chip comprises a memory chip.

28. The module of claim 25, further comprising at least one passive chip.

29. The module of claim 25, further comprising at least one memory controller.

30. The module of claim 25, further comprising at least one surface mount component.

31. The module of claim 25, wherein the flexible substrate comprises at least one connecting pad.

32. The module of claim 25, wherein the flexible top layer is transparent.

33. The module of claim 25, wherein the flexible top layer is made of a polymer material.

34. The module of claim 25, wherein the at least one flexible chip has a thickness that is less than 25 micrometers thick.

35. The module of claim 25, wherein at least one input/output interface of the at least one flexible chip is connected to at least one connecting pad of the flexible substrate.
